(19) United States
(12) Patent Application Publication
(10) Pub. No.: US 2026/0104456 A1
(43) Pub. Date: Apr. 16, 2026

(54) Vectorless Approach of Device under Test Testing

(71) Applicant: SK hynix Inc., Gyeonggi-do (KR)

(72) Inventor: Vladimir Valentinovich KOVALEV, San Jose, CA (US)

(21) Appl. No.: 18/912,497

(22) Filed: Oct. 10, 2024

(51) Int. Cl. G01R 31/319; G01R 31/28

(52) U.S. Cl. CPC G01R 31/31917; G01R 31/2834

(57) ABSTRACT

A method and associated system for testing a plurality of devices under test with internal sources of stimuli. The method feeds back outputs of the plurality of devices under test as inputs to the plurality of devices under tests, wherein the fed-back output is an internal source of the stimuli and represents informational entropy of each device under test. The method provides drive signals to each of the plurality of devices under test. The method collects results output from each of the plurality of devices under test provided with the drive signals and compares the results between the plurality of devices under test. The method identifies the devices passing the test as the devices where the results show homogenous behavior.

### BACKGROUND

### Field of the Invention

Embodiments of the present disclosure relate to device testing systems and methods.

### Description of the Related Art

The evaluation of the reliability and quality of a digital integrated circuit (IC) typically use several distinct testing phases, as described in U.S. Pat. No. 6,714,035 (the entire contents of which are incorporated herein by reference). These testing phases include a verification testing phase, a parametric testing phase, and a defect testing phase.

The verification testing phase is the initial phase in which the first prototype chips are tested to ensure that they match their functional specification, that is, to verify the correctness of the design. The verification testing phase checks that all design rules are adhered to, from layout to electrical parameters. The parametric testing phase ensures that components meet design specification for delays, voltages, power, etc.

The defect testing phase ensures that only defect-free production chips are packaged and shipped. The defect testing phase involves testing for a relatively large number of different physical defects that could be present.

One of the most practical methods for defect testing is to employ a fault model of the physical defects that can occur in the IC at a high level of abstraction, typically the logic level, and then develop algorithms, commonly referred to as Functional Test Vector (FTV) sets, for the modeled faults. Depending on the fault model and quality of the functional test vector set, the functional test vector set may cover a high percentage of the actual physical defects.

Processes for automated fault testing of large scale integrated circuits commonly employ what is known as a “stuck-at” fault model to emulate permanent faults that may occur during fabrication of the integrated circuit under test. In this model, the circuit description is modified or otherwise rendered to correspond to a stuck-at fault state, i.e., a continuous logic state of logic low level “0” or logic high level “1”. In a process known as fault simulation, the test vector sets developed based on the stuck-at fault model are applied to the IC and the value of the corresponding response is compared to the expected response value. After many faults are simulated and multiple test vectors run, an indication of the fault coverage of the applied test vector set is provided. If the fault coverage is unacceptably low, the test vector set may be modified to exercise portions of the circuit where undetectable faults lie.

### SUMMARY

In one embodiment of the present invention, there is provided a method for testing a plurality of devices under test with internal sources of stimuli. The method feeds back outputs of the plurality of devices under test as inputs to the plurality of devices under tests, wherein the fed-back output is an internal source of the stimuli and represents informational entropy of each device under test. The method provides drive signals to each of the plurality of devices under test. The method collects results output from each of the plurality of devices under test provided with the drive signals and compares the results between the plurality of devices under test. The method identifies the devices passing the test as the devices where the results show homogenous behavior.

In one embodiment of the present invention, there is provided a system for testing a plurality of devices under test with internal sources of stimuli. The system comprises the plurality of devices under test, wherein each of the plurality of devices under test comprises a switchboard to connect data flow between an output of a device under test back to an input of the device under test; a controller configured to provide a drive signal to the device under test; a register configured to collect the results over time of testing of the plurality of devices under test provided with respective drive signals; and a comparator configured to compare the results between the plurality of devices under test. The data flow between the output of the device under test back to the input of the device under test provides an internal source of the stimuli and represents informational entropy of the device under test.

Additional aspects of the present invention will become apparent from the following description.

### BRIEF DESCRIPTION OF THE DRAWINGS

FIG. 1 is a block diagram of a typical piece of automated test equipment.

FIG. 2 is an illustration of a typical test vector used in the automated test equipment.

FIG. 3 is a block diagram of a system for testing a device under test with an internal source of stimuli in accordance with one embodiment of the present invention.

FIG. 4 is a block diagram of a comparator for testing a plurality of devices under test in accordance with another embodiment of the present invention;

FIG. 5 is a block diagram of another comparator for testing a plurality of devices under test in accordance with still another embodiment of the present invention.

FIG. 6 is a flowchart illustrating a method for testing a plurality of devices under test with internal sources of stimuli in accordance with another embodiment of the present invention.

### DETAILED DESCRIPTION

Various embodiments are described below in more detail with reference to the accompanying drawings. The present invention may, however, be embodied in different forms and thus should not be construed as limited to the embodiments set forth herein. Rather, these embodiments are provided so that this disclosure is thorough and complete and fully conveys the scope of the present invention to those skilled in the art. Moreover, reference herein to “an embodiment,” “another embodiment,” or the like is not necessarily to only one embodiment, and different references to any such phrase are not necessarily to the same embodiment(s). Throughout the disclosure, like reference numerals refer to like parts in the figures and embodiments of the present invention.

The invention can be implemented in numerous ways, including as a process; an apparatus; a system; a computer program product embodied on a computer-readable storage medium; and/or a processor, such as a processor suitable for executing instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being suitable for performing a task may be implemented as a general component that is temporarily configured to perform the task at a given time or a specific component that is manufactured to perform the task. As used herein, the term ‘processor’ or the like refers to one or more devices, circuits, and/or processing cores suitable for processing data, such as computer program instructions.

A detailed description of embodiments of the invention is provided below along with accompanying figures that illustrate aspects of the invention. The invention is described in connection with such embodiments, but the invention is not limited to any embodiment. The scope of the invention is limited only by the claims. The invention encompasses numerous alternatives, modifications and equivalents within the scope of the claims. Numerous specific details are set forth in the following description in order to provide a thorough understanding of the invention. These details are provided for the purpose of example; the invention may be practiced according to the claims without some or all of these specific details. For clarity, technical material that is known in technical fields related to the invention has not been described in detail so that the invention is not unnecessarily obscured.

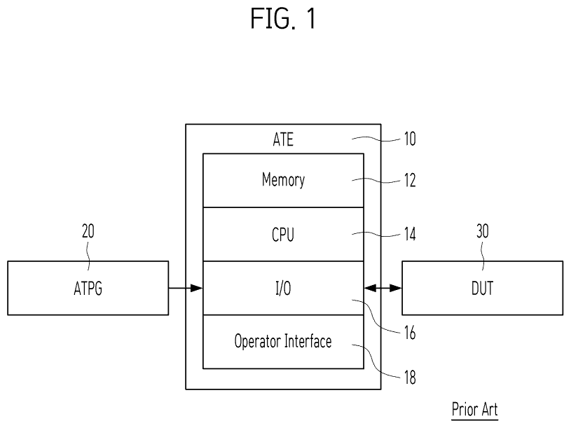

As illustrated in block diagram in FIG. 1 and as described in U.S. Pat. No. 6,732,312 (the entire contents of which are incorporated herein by reference), a typical automated test equipment ATE 10 comprises a central processing unit (CPU) 14, memory 12, input/output (I/O) 16 hardware, and usually some form of operator interface 18. The CPU 14 controls the operation of the ATE 10 employing a test vector stored in memory 12. The test vector, often produced by an external source 20, is transmitted to the ATE and loaded into memory 12 using the I/O hardware 16. During the automated test, the CPU 14 reads the test vector from memory and controls the I/O hardware 16 in order to affect a test of the device under test (DUT) 30. The operator interacts with the ATE through the operator interface 18. For simplicity, the system or IC being tested will be referred to hereinbelow as the device under test (DUT).

A typical automated test by ATE 10 employs a test vector. A test vector is a sequence of test operations to be performed and/or test values to be applied by the ATE to the system or IC under test, the DUT. In most modern ATEs, the test vector is a binary sequence owing to the overwhelming use of digital computers and memory in ATEs and the propensity for complex systems to be largely digital. Each test vector used by the ATE is normally generated by first consulting a design database or specification that identifies the functionality of the system or IC being tested. A test vector for a given DUT is generated by ‘mapping’ or translating the desired DUT functionality testing into the functionality testing capability of the ATE. The test vector is then typically transmitted to the ATE and stored in the ATE memory. The test vector subsequently controls the test of the DUT by the ATE.

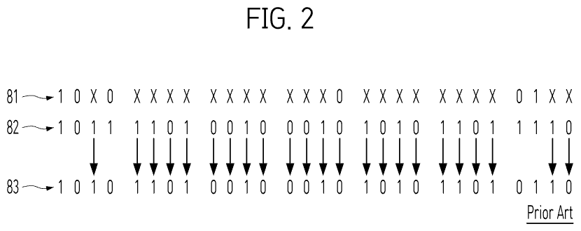

FIG. 2 illustrates an example of a typical test vector used with ATE 10. In the first line 81 of FIG. 2, a sequence generated by an automated test pattern generator (ATPG) is shown including ‘don't care’ states, depicted as X's. In the next line 82, a random binary sequence, as might be generated by the random sequence generator, is shown. Finally, in the last line 83 of FIG. 2, the completely specified test vector, as it exists after replacing the ‘don't care’ states with corresponding bits from the random sequence, is illustrated. It is the last sequence of the last line 83 of FIG. 2 that is conventionally transmitted to and stored in the memory of the ATE. The filled test vector is often referred to as a “completely specified” test vector to distinguish it from the test vector including ‘don't care’ states.

Conventionally, the completely specified test vector is transmitted to and stored in the memory of the ATE. Test vectors can be very large and can occupy significant amounts of memory in the ATE. In many cases, as detailed in the '312 patent, the memory necessary to store the test vectors may account for as much as 50% of the cost of the ATE. Moreover, even when ATE memory cost is not a significant factor, the time associated with transmitting the test vector to the ATE memory can be significant. Additionally, a device may require more memory for storing test vectors than is available in a given ATE.

In general, prior art approaches for device testing can be classified into two main categories utilizing: a) deterministic stimuli generated by the ATPG tools applied on inputs of the DUT and b) non-deterministic stimuli produced by pseudo random number generator(s). Regardless of input, a mandatory comparison is made to expected values of outputs of the DUT directly or to an expected signature collected by a multiple input shift register (MISR). Both methods require significant amount of time and/or resources especially in consideration of todays size of silicon chips.

### Inventive Device Testing

The present disclosure provides a method and system for device testing without the need to have test vectors generated by ATPG tools. Consequently, the method and system for device testing eliminates the need for test vectors validation (especially the verification part).

The invention may be considered for the purpose of illustration to have two parts. In the first part, informational entropy of the DUT itself is used as a source of stimuli, a switchboard connects outputs of the DUT itself to inputs of the DUT, and a control circuit drives continuous signals (including, but not limited to clocks, resets, shift enables etc.) to the DUT. In this case, information entropy is generated by the state of all flops in the DUT being shifted due to pseudo-random values, with this random-type output (the information entropy) being feedback as an input to the DUT. In the second part, the invention makes use of the fact observed by the inventors that “good” or “healthy” devices behave same way under test and produce an equal reaction on outputs, given that only manufacturing defects are being targeted. Outputs are captured on the MISR.

The behaviors of “good” or “healthy” devices in one embodiment is recognized by those devices having homogeneous results, that is those devices having the same or nearly the same results. Accordingly, the elimination of the mandatory use of ATPG tools as a source of stimuli and expected values, as well consecutive vector validation makes this novel method and system for device testing useful at scan chains (where flops are connected sequentially to form a shift register of a given length to perform shift in/out operations) and useful at production testing.

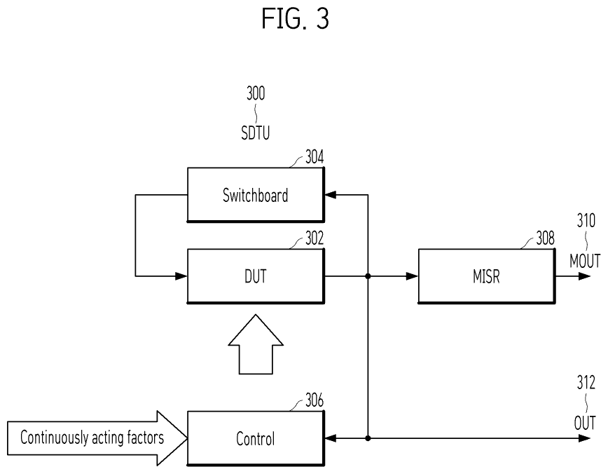

FIG. 3 is diagram of a single device test unit (SDTU) 300 utilized in the present disclosure for device testing. The SDTU 300 operates as follow: The DUT 302 upon operation generates output flow of data indicated by the arrows exiting DUT 302. A switchboard 304 commutates data flow back into DUT inputs, forming a recursive entropy flow. The switchboard 304 has two modes of operation: a) plain—static commutation which does not purposely change during a test; b) featured—dynamic commutation controlled by the recursive entropy flow, where input data is scrambled to provide an extra degree of randomization (i.e., to increase the randomness of the input data to the DUT). Control circuit 306 provides DUT 302 with vital continuous signals. It has modes of operation: a) plain—static relationship of control signals; b) featured—dynamic (random) relationship of control signals by recursive entropy flow. As illustrated in FIG. 3, continuously acting (or varying) factors are applied as an input to control circuit 306. A multiple input shift register (MISR) 308 collects a signature over the time of testing. As illustrated in FIG. 3, a MOUT signal 310 from MISR 308 is provided for analysis of the DUT. As illustrated in FIG. 3, an OUT signal 312 from DUT 302 can also be provided for analysis of the DUT. The control circuit 306 and the MISR 308 may contain memory elements for storage of the outputs from the testing.

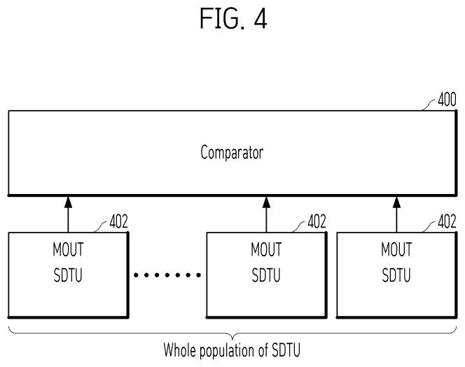

An explanation of the detection of “good” DUT's follows from diagram of FIG. 4. FIG. 4 shows a comparator 400 comparing the outputs of a plural single units 402. The plural single units 402 have the same components as SDTU 300 of FIG. 3. The plural single units 402 provide MOUT signals to comparator 400.

The detection of “good” DUTs (those DUTs having equal outputs) proceeds as follow: a) provide MOUT signals from all SDTUs 402 (having a single DUT) to comparator 400, b) compare MOUT signals from each MISR of each SDTU 402 to each other, c) sort out consistently equal MOUT signals from the plural SDTUs 402.

As illustrated in FIG. 4, the whole population of the plural SDTUs 402 can be compared. However, in one embodiment, the present disclosure does not require that the whole population be compared in order to assess whether the population of SDTUs as a whole is of acceptable quality (i.e., whole population would be expected to show “good” results if all were tested). In some cases, it may be not practical to compare results from all the plural SDTUs 402 due to demand of external computation resources, instrumental limitations, etc. In one embodiment, the number N of the plural SDTUs 402 (compared to the whole population that need to be tested for assessment of quality of the whole population) will depend on the manufacturing yield. For example, if a manufacturing process is very mature, e.g., with a fab yield of 99%, then even with a sample size of only 5 percent of the total population a mistake of only 8.09E-06 would be predicted meaning that statistically only that fraction of the whole population would be expected not to have “good” results, which is acceptable. On other hand, if yield is 77% then with the same sample size of 5 percent of the total population, the probability of a mistake increases to 7.19E-02, (or 7%) which is quite large and not acceptable. For a yield of 77% and a sample size of 25 percent of the total population, the probability of a mistake occurring decreases to 1.05E-03, which for OEM customers may not be acceptable, and even larger sample sizes may be needed.

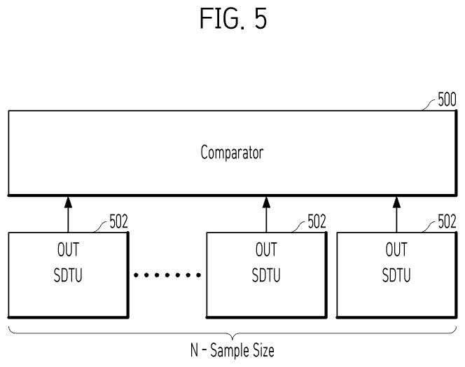

In another embodiment, the method of sampling which of the plural SDTUs 402 to compare can be based on yield information. A diagram of such a sampling method is provided in FIG. 5. FIG. 5 shows a comparator 500 comparing the outputs of N number of plural SDTUs 502. The plural SDTUs 502 have the same components as SDTUs 300 of FIG. 3. The plural SDTUs 502 provide OUT signals to comparator 500.

In one embodiment, a detection operates as follow:
a) a sample size of N of the plural SUs is chosen,
b) advance the test by one test step for the whole sample size,
c) at the end the test step, compare outputs,
d) choose a group of “good” devices by equality (or homogeneity) of outputs and a chosen tactic such as yield (where majority of the devices are expected to the “good” device and a minority of the devices would be expected to have unequal outputs),
e) store identifiers (e.g. identifying numbers) for each of the devices from the group defined in step “c”=>STORAGE (n),
f) compare identifiers of current group to identifiers from previous Test Step <=STORAGE (n−1),
g) take the intersection of both groups with same “good” property, store the identifiers of the same devices in both groups which have the same “good” property in current storage: STORAGE(n)∩STORAGE (n−1)=>STORAGE(n), and
h) Proceed to “b”.

In this embodiment, the choice of N is an important factor. One factor influencing the size of N is the maturity of the device manufacturing, and hence the manufacturing yield for a population of devices being tested (as noted in the examples of yield and sample size N noted above). Another factor influencing the choice of the size of N for the tactic (or criterion for pass) is based on both the majority or minority of “good devices” and the instrumental capabilities. Instrumental capabilities (like the number of DUTs that can be simultaneously tested) may be limited by available tester channels and hence limit the size of N that can be practically sampled.

Since a sample represents only a fraction or part of the whole population, in order to make a correct approximation of sample representation, a probabilistic model can be used in one embodiment. Probability of making mistake within one sample could be used to define a sample size (N). Following equitation defines such probability in the case if the majority of good devices (i.e., the majority devices show same result) for a given population chosen:

$${P}_{maj} = \frac{{C}_{{m}_{d}}^{{n}_{d}} \times {C}_{{m}_{g}}^{{n}_{g}}}{{C}_{{m}_{tot}}^{{n}_{sample}}}$$

Where:

$${C}_{m}^{n}$$

Combination of m taken by n.
mₜₒₜ—Total number of devices;
nₛₐₘₚₗₑ—Sample size, have to be odd number to avoid 50/50 stuck point;
Y—Immanent manufacturing yield;
m_{d}—Total number of defect devices in whole population, derived from yield as follow:

$${m}_{d} = {m}_{tot} - \frac{{m}_{tot} \times Y}{100}$$

n_{d}—Number of defect devices in the sample size, since the majority tactic was chosen, then violations (hence mistakes) will occur when defect devices in the sample prevail or is greater than the number of good devices, so that n_{d} is defined as:

$${n}_{d} = ROUNDUP ( \frac{{n}_{sample}}{2} )$$

m_{g}—total number of good devices in whole population, derived from yield as follow:

$${m}_{g} = \frac{{m}_{tot} \times Y}{100}$$

n_{g}—number of good devices in the sample defined as follow:

$${n}_{g} = {n}_{sample} - {n}_{d}$$

In the table below, the calculation results are shown with a defects parts per million (DPPM) requirement set to 10:

| | | | Probability of | Probability of | Probability of |
|---|---|---|---|---|---|
| | | | mistake within | mistake within | mistake within |
| | | | majority tactic, | majority tactic, | majority tactic, |
| Total SU | Yield, % | Sample Size | sample size = 5 | sample size = 15 | sample size = 25 |
| 1600 | 99 | 5 | 8.09E−06 | 7.64E−14 | 4.13E−23 |
| | 97 | 15 | 2.40E−04 | 1.94E−09 | 1.11E−14 |
| | 95 | 25 | 1.09E−03 | 1.29E−07 | 1.42E−11 |
| | 93 | | 2.90E−03 | 1.82E−06 | 1.18E−09 |
| | 91 | | 5.94E−03 | 1.24E−05 | 2.81E−08 |
| | 89 | | 1.04E−02 | 5.46E−05 | 3.25E−07 |
| | 87 | | 1.65E−02 | 1.82E−04 | 2.33E−06 |
| | 85 | | 2.42E−02 | 4.94E−04 | 1.19E−05 |
| | 83 | | 3.37E−02 | 1.15E−03 | 4.73E−05 |
| | 81 | | 4.48E−02 | 2.39E−03 | 1.54E−04 |
| | 79 | | 5.76E−02 | 4.51E−03 | 4.30E−04 |
| | 77 | | 7.19E−02 | 7.87E−03 | 1.05E−03 |

### Operational Method

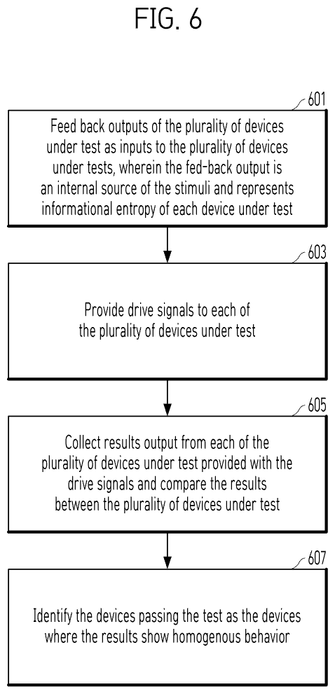

FIG. 6 is a flowchart illustrating a method for testing a plurality of devices under test with internal sources of stimuli. The method at 601 feeds back outputs of the plurality of devices under test as inputs to the plurality of devices under tests, wherein the fed-back output is an internal source of the stimuli and represents informational entropy of each device under test. The method at 603 provides drive signals to each of the plurality of devices under test. The method at 605 collects results output from each of the plurality of devices under test provided with the drive signals and compares the results between the plurality of devices under test. The method at 607 identifies the devices passing the test as the devices where the results show homogenous behavior.

In one method embodiment, the feeding back outputs may utilize a switchboard to connect data flow between an output of a device under test back to an input of the device under test. In this method embodiment, the switchboard may provide dynamic commutation of the feed-back to increase randomness of the feed-back.

In one method embodiment, the providing drive signals utilizes a controller providing a continuous signal to drive the device under test. In one method embodiment, the collecting results output from each of the plurality of devices under test may utilize a register to collect the results over time of testing of the device under test.

In one method embodiment, the collecting results output from each of the plurality of devices under test may collect the results from a population of devices being manufactured. The collected results may be from a whole of the population. In another method embodiment, the collected results may be from a fraction of the population. The fraction of the population from which the results are collected may be determined based at least on a total number of devices in the population and an expected manufacturing yield.

In one method embodiment, the identifying the devices passing the test does not utilize expected output values derived from an outside source.

### System Implementation

In one embodiment of the present invention, there is provided a system for testing a plurality of devices under test with internal sources of stimuli from the devices under test. The system comprises the plurality of devices under test, wherein each of the plurality of devices under test comprises a) a switchboard to connect data flow between an output of a device under test back to an input of the device under test, b) a controller configured to provide a drive signal to the device under test, c) a register configured to collect the results over time of testing of the plurality of devices under test provided with respective drive signals, and d) a comparator configured to compare the results between the plurality of devices under test. In this system, the data flow between the output of the device under test back to the input of the device under test provides an internal source of the stimuli and represents informational entropy of the device under test.

In one system embodiment, the comparator can be configured to collect results output from each of the plurality of devices under test and compare the results between the plurality of devices under test. The comparator can be configured to identify the devices passing the test as the devices where the results show homogenous behavior.

In one system embodiment, the switchboard can be configured to provide dynamic commutation of the feed-back to increase randomness of the feed-back.

In one system embodiment, the controller can be configured to provide a continuous signal to drive the device under test.

In one system embodiment, the comparator can be configured to collect the results from a population of devices being manufactured. The comparator can be configured to collects the results from a whole of the population. Alternatively, the comparator can be configured to only collect the results from a fraction of the population. The fraction of the population from which the results are collected can be determined based at least on a total number of devices in the population and an expected manufacturing yield.

In one system embodiment, the comparator can be configured to not to utilize expected output values for the devices under test derived from an outside source (that is from a source outside the systems described above).

The systems described above permit usage of immanent informational entropy of a DUT to drive the input stimuli and eliminate the need for deterministic and nondeterministic expected values generation which other industrial tools do. In one embodiment, by selecting the “good devices” by their homogeneous behavior, it is not necessary to compare the output results from a device under test against expected values as other industrial tools do.

Although the foregoing embodiments have been illustrated and described in some detail for purposes of clarity and understanding, the present invention is not limited to the details provided. There are many alternative ways of implementing the invention, as one skilled in the art will appreciate in light of the foregoing disclosure. The disclosed embodiments are thus illustrative, not restrictive. The present invention is intended to embrace all modifications and alternatives recognized by one skilled in the art.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, or a combination of one or more of them. Apparatus, devices, and machines for processing data in the invention can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network. The computer program can be embodied as a computer program product as noted above containing a computer readable medium.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

What is claimed is:

1. A method for testing a plurality of devices under test with internal sources of stimuli, the method comprising:
feeding back outputs of the plurality of devices under test as inputs to the plurality of devices under tests, wherein each of the fed-back output is an internal source of the stimuli and represents informational entropy of each device under test;
providing drive signals to each of the plurality of devices under test;
collecting results output from each of the plurality of devices under test provided with the drive signals and comparing the results between the plurality of devices under test; and
identifying the devices passing the test as the devices where the results show homogenous behavior.

2. The method of claim 1, wherein the feeding back outputs comprises utilizing a switchboard to connect data flow between an output of each of the plurality of devices under test back to an input of each of the plurality of devices under test.

3. The method of claim 2, wherein the switchboard provides dynamic commutation of the feed-back to increase randomness of the feed-back.

4. The method of claim 2, wherein the providing drive signals comprises utilizing a controller providing a continuous signal to drive the plurality of devices under test.

5. The method of claim 4, wherein the collecting results output from each of the plurality of devices under test comprises utilizing a register to collect the results over time of testing of the plurality of devices under test.

6. The method of claim 1, wherein the collecting results output from each of the plurality of devices under test comprises collecting the results from a population of devices being manufactured.

7. The method of claim 6, wherein the collecting the results from the population comprises collecting the results from a whole of the population.

8. The method of claim 6, wherein the collecting the results from the population comprises collecting the results from a fraction of the population.

9. The method of claim 7, wherein the fraction of the population from which the results are collected is determined based at least on a total number of devices in the population and an expected manufacturing yield.

10. The method of claim 1, wherein the identifying the devices passing the test does not utilize expected output values for the devices under test derived from an outside source.

11. A system for testing a plurality of devices under test with internal sources of stimuli, the system comprising:
the plurality of devices under test, wherein each of the plurality of devices under test comprises
a switchboard configured to connect data flow between an output of each of the plurality of devices under test back to an input of each of the plurality of devices under test;
a controller configured to provide a drive signal to each of the plurality of devices under test;
a register configured to collect the results over time of testing of the plurality of devices under test provided with respective drive signals; and
a comparator configured to compare the results between the plurality of devices under test,
wherein the data flow between the output of each of the plurality of devices under test back to the input of each of the plurality of devices under test provides an internal source of the stimuli and represents informational entropy of each device under test.

12. The system of claim 11, wherein the comparator is configured to collect results output from each of the plurality of devices under test and compare the results between the plurality of devices under test.

13. The system of claim 11, wherein the comparator is configured to identify the devices passing the test as the devices where the results show homogenous behavior.

14. The system of claim 11, wherein the switchboard is configured to provide dynamic commutation of the feed-back to increase randomness of the feed-back.

15. The system of claim 11, wherein the controller is configured to provide a continuous signal to drive the plurality of devices under test.

16. The system of claim 11, wherein the comparator is configured to collect the results from a population of devices being manufactured

17. The system of claim 16, wherein the comparator is configured to collect the results from a whole of the population.

18. The system of claim 11, wherein the comparator is configured to collect the results from a fraction of the population.

19. The system of claim 18, wherein the fraction of the population from which the results are collected is determined based at least on a total number of devices in the population and an expected manufacturing yield.

20. The system of claim 11, wherein the comparator is configured to not to utilize expected output values for the devices under test derived from an outside source.
